(19) United States
(12) Patent Application Publication
(10) Pub. No.: US 2015/0093503 A1
(43) Pub. Date: Apr. 2, 2015

(54) TANTALUM OXIDE COATINGS

(71) Applicants: Anna Louise Colley, Prescot (GB); Kevin David Sanderson, Skelmersdale (GB); Gary Robert Nichol, Warrington (GB); David Alan Strickler, Toledo, OH (US)

(72) Inventors: Anna Louise Colley, Prescot (GB); Kevin David Sanderson, Skelmersdale (GB); Gary Robert Nichol, Warrington (GB); David Alan Strickler, Toledo, OH (US)

(73) Assignee: PILKINGTON GROUP LIMITED, LATHOM (GB)

(21) Appl. No.: 13/261,810

(22) PCT Filed: Aug. 16, 2012
(86) PCT No.: PCT/GB2012/051999

§ 371 Date: Dec. 8, 2014

(30) Foreign Application Priority Data
Aug. 18, 2011 (GB) 1114242.9

(51) Int. Cl. C03C 17/00; C03C 17/245; C23C 16/40; C23C 16/46; H01L 31/18; C23C 16/02

(52) U.S. Cl. CPC C03C 17/002; H01L 31/18; C23C 16/0209; C23C 16/405; C23C 16/46; C03C 17/245
USPC 427/226

(57) ABSTRACT

A process for the deposition of tantalum oxide on a substrate from a precursor mix comprising a halide of tantalum and an organic oxygen source. The process lends itself in particular to on line coating during the float glass manufacturing process, where residual heat is used to effect thermal decomposition of the organic oxygen source.

The invention concerns a process for growth of tantalum oxide on a substrate.

Tantalum oxide possesses a number of physical and optical properties which give rise to various applications in inter alia semiconductor devices and as a coating on flat substrates such as glass. These properties include a high dielectric constant; a large band gap; high electrical resistance; good chemical and thermal stability and high refractive index.

One such application concerns the use of tantalum oxide as a buffer layer material in cadmium-tellurium based photovoltaic (PV) devices. Such devices typically comprise a heterjunction formed by layers of CdS and CdTe semiconductor, deposited on a transparent substrate. The substrate is typically non-conducting (e.g. glass) so a thin layer of transparent conductive oxide (TCO) is included between the substrate and the semiconductor layers to serve as a front contact current collector.

Inclusion of a buffer layer between the semiconductor junction structure and the TCO layer offers a number of advantages: for example, formation of localized junctions within the TCO is avoided; electrical shunting through the semiconductors is reduced and adhesion between the layers is improved. U.S. Pat. No. 6,169,246 describes the use of zinc stannate buffer layers in PV devices.

Ta₂O₅ thin films have been prepared by a number of techniques including sputtering, Atomic Layer Deposition (ALD), and Chemical Vapour Deposition (CVD). Previous workers have reported difficulty in achieving polycrystaline films at deposition temperatures below 700° C. although this has been achieved by ALD at temperatures above 400° C. (see k. Kupli et al, Thin solid films, 1995, 260, 135).

CVD growth of tantalum oxide has been done for use as a high dielectric material in capacitors, gates etc in integrated circuits (e.g. U.S. Pat. No. 5,292,673). For these applications, only relatively thin films (of the order of 10 nm) are required.

Tantalum fluoride has been suggested as a precursor for use in CVD deposition of tantalum oxide (e.g. U.S. Pat. No. 6,201,276 and US2004/0005749 A1).

US2009/030657 A1 discloses growth of crystalline Ta₂O₅ by CVD and TaF₅ is mentioned as a possible precursor. Sources of oxygen and hydrogen are used along with a water vapour generator and catalyst for the inlet streams of molecular oxygen and hydrogen. Crystallographic orientation can be influenced by varying the ratio of H₂:O₂ but deposition is done on a ruthenium containing material whose surface has a profound effect of the tantalum oxide growth.

During the float glass manufacturing process, a continuous supply of molten glass is fed to a bath of molten tin. The molten glass naturally distributes over the surface of the tin and, as it solidifies, a continuous flat ribbon of glass is drawn off. One of the major advantages of the float glass manufacturing technique is that it provides high quality flat glass with a smooth surface, without the need for further grinding or polishing.

CVD deposition of coatings may be performed on float glass either ‘off-line’ or ‘on-line’.

In off-line CVD deposition, the coating is done on the glass after it has been cut from the ribbon to form separate sheets and removed from the float glass manufacturing apparatus.

In on-line CVD deposition, reactants are directed to the surface of the continuous glass ribbon e.g. in the float bath or soon after it exits. Thus heat arising from the float glass production process is utilised to facilitate the CVD reaction. U.S. Pat. No. 6,238,738 provides a general description of apparatus and methods used in the on-line coating of glass substrates.

Typical glass ribbon temperatures encountered during the float glass manufacturing process, which facilitate CVD deposition including a process according to the present invention, range from about 750° C. to 580° C. in the float bath and about 580° C. to 400° C. in the lehr.

In addition, on-line CVD deposition offers a number of other advantages including those associated with the use of a continuous process rather than a batch process. Nevertheless float glass production is a dynamic process wherein the coating is applied to a moving glass substrate. Deposition must be done at a rate which gives rise to useful coating thicknesses for the line speeds of the glass substrates typically seen. To this end, suitable reactions must be discovered and employed.

Moreover, in many CVD processes the reactants employed will readily react when brought together and hence need to be kept separate until they are brought to the desired reaction site (i.e. the substrate surface). GB2044137A describes an example of a process where reactants are brought to a hot glass substrate in laminar streams. Such systems require relatively complex apparatus and careful process control: a CVD process employing reactants that may be pre-mixed and brought to the substrate in a single, homogeneous stream is easier to control and allows for smooth even coating with simpler apparatus.

According to the invention, a process for the deposition of tantalum oxide on a substrate comprises the steps set out in claim 1 attached hereto.

Preferably, the halide of tantalum is selected from tantalum fluoride, tantalum chloride, more preferably tantalum fluoride.

Preferably, the organic source of oxygen comprises an ester having an alkyl group with a β hydrogen atom. More preferably, the ester is selected from ethyl acetate, ethyl formate, methyl formate and t-butyl acetate. Most preferably the ester is ethyl acetate.

Preferably, ethyl acetate comprises at least 0.75% of the total precursor mixture.

A process according to the invention is conveniently done on glass, particularly the surface of a continuous glass ribbon during a float glass production process.

Preferably, the precursor mixture is brought into contact with the glass at a point where the glass temperature is between 400° C. and 750°, more preferably between 580° C. and 750° C. most preferably between 580° C. and 650° C.

Preferably the precursor mixture is maintained at a temperature of between 100° C. and 300° C., more preferably between 140° C. and 180° C.

The present invention offers a process for deposition of tantalum oxide layers by CVD. The deposition rates achieved render the process suitable for use on-line, during float glass manufacture although this application should not be seen as limiting. Moreover, reactants are employed which may be pre-mixed, i.e. mixed together before delivery to the deposition site where reaction may be assisted by heat arising from the float glass process.

The invention will now be described by non-limiting example, with reference to the appended figures in which:

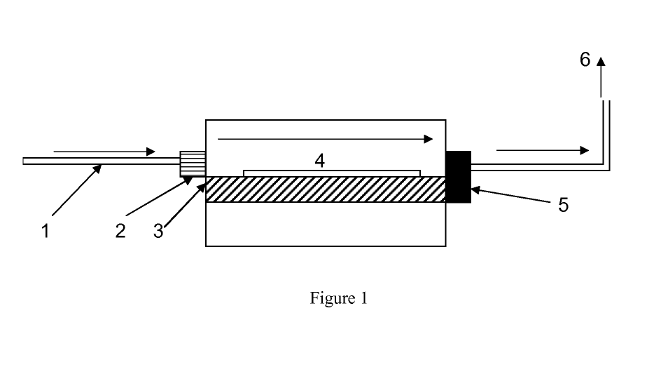

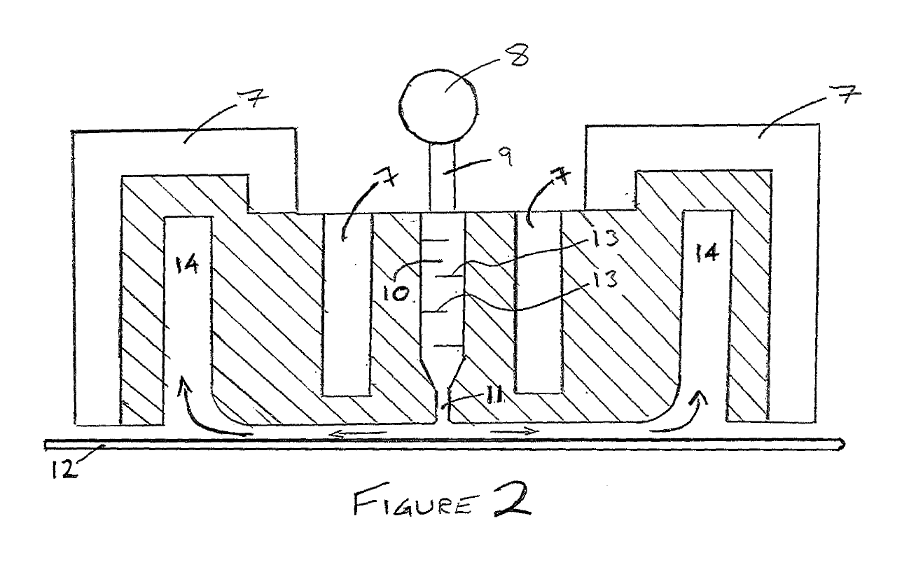

FIG. 1 illustrates a laboratory scale static coater used trial various precursors and reaction conditions for CVD coating of a substrate;

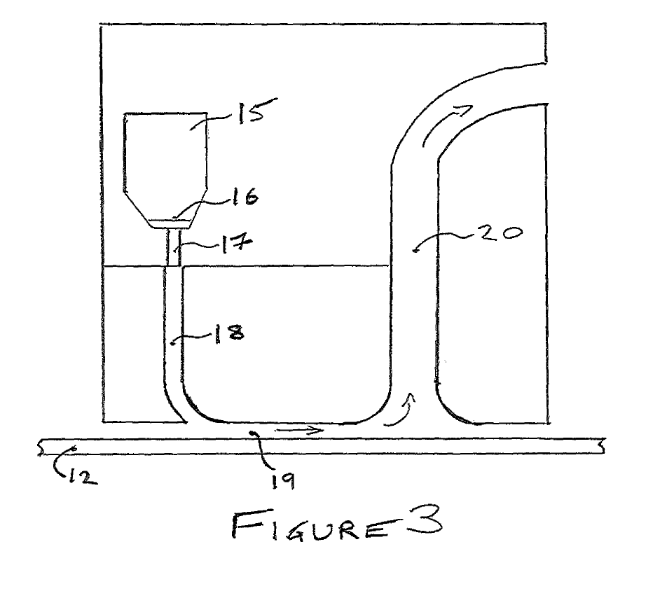

FIG. 2 illustrates a dynamic coating beam typically used on moving glass substrates such as encountered during the float glass manufacturing process;

FIG. 3 illustrates an alternative coating beam and

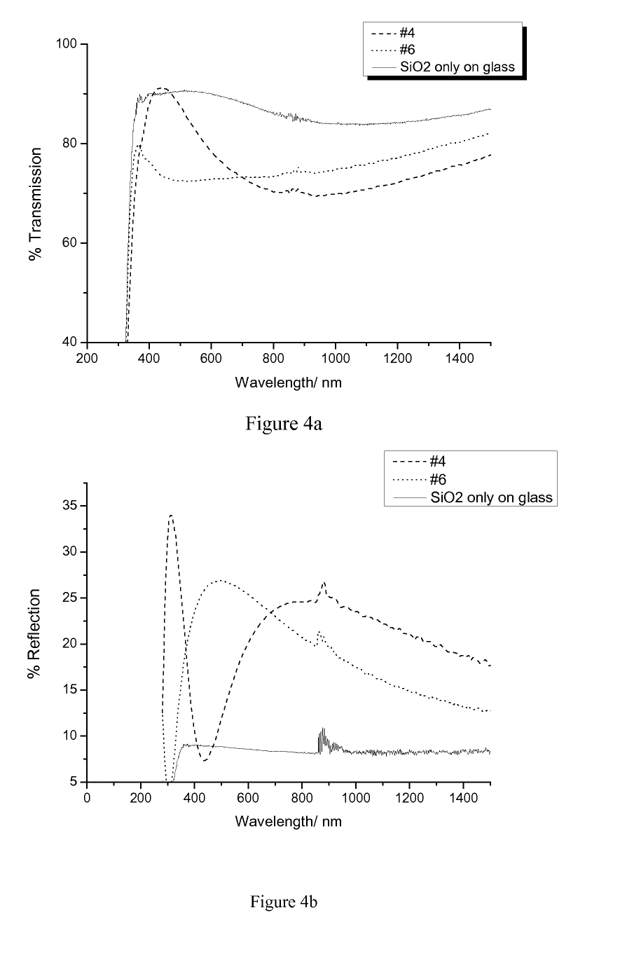

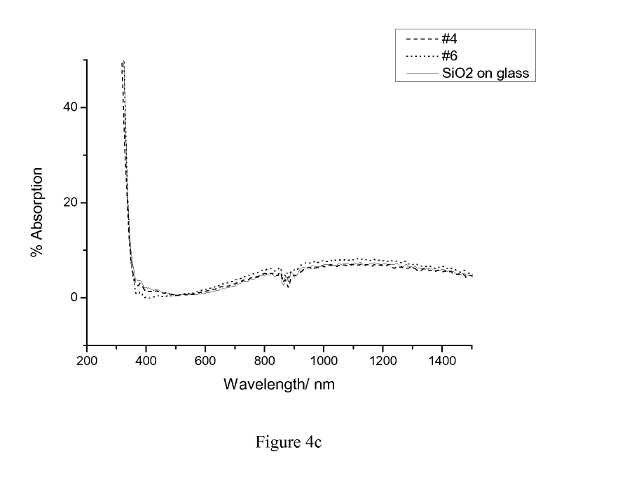

FIGS. 4a-4c shows various optical properties of tantalum oxide coatings produced according to the invention.

Referring to FIG. 1, initial trials for the deposition of Ta₂O₅ were performed on a laboratory scale ‘static coater’ wherein the premixed precursors move towards the coater through a heated line 1 before they reach baffle section 2 which equalises the precursor flow before it enters the sealed coating section. The glass substrate 4 sits on a heated carbon block 3 which is heated to the desired temperature using either heating elements (not shown) inserted inside the carbon block or by an induction coil (not shown) around the sealed coating section. Any unreacted precursor or by products are then directed towards fish tail exhaust 5 and continue towards the incinerator 6. The arrows show the direction in which the gaseous mixture moves.

Referring to FIG. 2, a coating beam for supplying precursors according to the invention to a substrate has a generally linear configuration and is shown in cross section. The beam comprises a box section framework having cavities 7 through which a fluid such as oil may be circulated to maintain the temperature of the apparatus by heat exchange.

Precursor gas mixture is supplied via conduit 8 (which may also be fluid cooled) extending along the coating beam, and through drop lines 9 spaced along conduit 8. The precursor gas mixture, so delivered by drop lines 9 enters a delivery chamber 10 and then passes through passage 11 to the surface region of glass substrate 12 where they flow in the direction of the arrows.

Baffles 13 may be included in the delivery chamber to provide for a more uniform flow and distribution of precursor materials across the substrate 12.

Spent precursor materials are removed through exhaust chambers 14.

The coating beam illustrated in FIG. 2 is referred to as a bi-directional beam because the precursor mixture flows in two directions across the substrate 12 on exiting passage 11. (The two directions correspond to ‘upstream’ and ‘downstream’ for a dynamic coater below which the substrate is passed).

Referring to FIG. 3, a unidirectional coating beam has a number of components corresponding with components of the bi-directional device.

Precursor gas mixture is provided via a supply duct 15 through an aperture 16 which extends along the beam, and into gas flow restrictor 17. From restrictor 17, the gas passes through channel 18 to a coating chamber 19 opening on to substrate 12 and then to exhaust channel 20.

A unidirectional coating beam is described in more detail in EP 0 305 102.

Three different precursor were initially trialled on a small static CVD coater according to FIG. 1. Two of the precursors, Tantalum Chloride and Tantalum Fluoride were chosen due to their relatively high volatility thus making them suitable for the standard delivery system used by atmospheric pressure CVD i.e flowing nitrogen carrier gas was passed through bubblers containing the precursors which became entrained in the nitrogen. Tantalum ethoxide is not as volatile and therefore was not suitable for delivery through a bubbler set up. However, as it is liquid above 21° C. and dissolves in a number of organic solvents it was deemed suitable for delivery through a syringe driver delivery system whereby the precursor is introduced to the nitrogen carrier in a metered fashion via a syringe. Precursor delivery by these, and a variety of other methods, is well known to a person skilled in the art and does not warrant further description here.

Ethyl acetate improved the growth properties of the coatings obtained from both of the tantalum halide precursors. Nevertheless tantalum fluoride, as the most volatile, was selected for further investigation. The growth of tantalum oxide from tantalum ethoxide was also improved by the addition of ethyl acetate but the XRD results revealed that the coating grown with tantalum ethoxide was amorphous while the coatings grown from tantalum fluoride were crystalline.

Tantalum Fluoride is a solid with a melting point of 96.8° C. and a boiling point of 229.5° C. The best tantalum oxide coatings, in terms of even coating coverage and low absorbance, were achieved with ethylacetate 0.75% of the total precursor mixture and above.

Tantalum oxide coatings were shown to deposit on the heated substrate with other organic oxygen compounds. These organic oxygen compounds were preferably an ester with an alkyl group with β hydrogen to give good growth rates. Table 1 shows the different oxidants and the condition used. In all the examples the substrate was static, positioned next to a uni-directional coater reactor head. The substrate was heated to 600 C and was held under the reaction mixture for 15 seconds. The glass substrate was float glass which had been initially provided with a silica coating as described in European patent EP 275 662B. To deposit the tantalum oxide a precursor gas mixture was developed comprising tantalum fluoride, the organic oxygen precursor and nitrogen. Nitrogen was used in the precursor mixture as a carrier for the reactants. The precursor mixture was prepared by simultaneously introducing all four gas streams through a manifold system. The temperature of the precursor line was kept above 160° C. to prevent the adduct reaction of the precursors and solidification and blocking in the line.

In general, the temperature of the delivery line should be maintained above that at which the precursors will form adducts and, or solidify and below that at which the precursors will pre-react or otherwise decompose significantly. This range might be further limited by the performance of attendant equipment: e.g. valves employed in the delivery system will typically have an associated temperature above which they fail.

For the present invention, delivery line temperatures in the range of 100° C. to 300° C. are especially preferred.

In coating number 6 the isoproponol burned in the reactor leaving only particulate tantalum oxide on the glass, the corresponding deposition rate is therefore quoted as 0 nm/second.

TABLE 1

| | Flow Rates (litres/minute) | | | | |
|---|---|---|---|---|---|
| | | Organic | | | |
| Coating | Tantalum | oxygen | | Thickness/ | Growth |
| No. | oxide | compound | Nitrogen | nm | Rate nm/s |
| 1 | 0.85 | 0.24 Ethyl | 12 | 180 | 12 |
| | | acetate | | | |
| 2 | 0.85 | 0.24 Ethyl | 12 | 170 | 11 |
| | | Formate | | | |
| 3 | 0.85 | 0.24 Methyl | 12 | <100 | 5 |
| | | formate | | | |
| 4 | 0.85 | 0.24 t-butyl | 12 | 250 | 17 |
| | | acetate | | | |
| 5 | 0.85 | 0.24 Water | 12 | 0 | 0 |
| 6 | 0.85 | 0.24 Isopro- | 12 | 0 | 0 |
| | | ponol | | | |

A number of experiments were carried out using a larger scale dynamic coater. The glass was heated to 600 C on a conveyor furnace to simulate the coating reaction conditions of a float glass process. The glass was moving at a speed of 72 m/hr under the bi-directional CVD coater head. The amount of the oxidants; oxygen and the ethylacetate were varied and the resulting coatings were analysed. Under these conditions growth of around 12 nm/s was achieved. The conditions used and the results of some of the analysis are shown below in Table 2.

TABLE 2

| | | | | | | | | Total |
|---|---|---|---|---|---|---|---|---|
| | | | | | | | | TaO₂ |
| | TaO₂/ | EtOAc/ | O₂/ | Ratio | Ratio | | Roughness | Thickness/ |
| Sample | Imin⁻¹ | Imin⁻¹ | Imin−1 | EtOAc:TaO₂ | O₂:TaO₂ | Haze | Ra/nm | nm |
| #1 | 0.06 | 0.600 | 1.0 | 10 | 16.7 | 0.6 | 4.8 | 67-75 |
| #2 | 0.06 | 0.762 | 2.0 | 12.7 | 33.3 | 0.61 | 3.1 | 87-90 |
| #3 | 0.06 | 0.459 | 1.0 | 7.7 | 16.7 | 0.67 | 3.6 | 63-67 |
| #4 | 0.10 | 0.459 | 2.0 | 4.59 | 20 | 0.8 | 1.6 | 126 |
| #5 | 0.10 | 0.600 | 0.0 | 6 | 0 | 0.58 | 3.5 | 113 |
| #6 | 0.06 | 0.762 | 0.0 | 12.7 | 0 | 0.48 | 6.8 | 86-90 |
| #7 | 0.10 | 0.762 | 1.0 | 7.6 | 10 | 0.49 | 2.9 | 102 |

FIGS. 4a 4b and 4c respectively show the transmission, reflection and absorption graphs for two of the seven coatings that show the two extremes in the shape of the reflection plot as well as the base SiO₂ coated glass. The shift in the spectra is due to some variations in the morphology of the Tantalum oxide grown. All of the coatings showed negligible absorption.

Diffraction studies showed that all coatings had the TaxOy (200) reflection at 22.7 degrees 2-theta as the strongest reflection. The (200) reflections occurred at a lower 2-theta angle than the unstrained position indicating the presence of tensile strain in a direction perpendicular to the coating surfaces.

TOF-SIMS depth profile analysis was performed on the samples (#1-#7 of table 2). The positive ion profile analysis indicated that the level of tantalum detected through the coating remained relatively constant throughout the film.

1-14. (canceled)

15. A process for deposition of tantalum oxide on a substrate comprising the steps of:
forming a fluid precursor mixture comprising a halide of tantalum and an organic source of oxygen; and
bringing said mixture into contact with the surface of the glass at a point where the temperature of the glass is sufficient to effect thermal decomposition of the organic source of oxygen.

16. The process according to claim 15, wherein the halide of tantalum is selected from tantalum fluoride, tantalum chloride.

17. The process according to claim 16, where the halide of tantalum is tantalum fluoride.

18. The process according to claim 15, wherein the organic source of oxygen comprises an ester having an alkyl group with a β hydrogen atom.

19. The process according to claim 18, wherein the ester is selected from ethyl acetate, ethyl formate, methyl formate and t-butyl acetate.

20. The process according to claim 19, wherein the ester is ethyl acetate.

21. The process according to claim 20, wherein ethyl acetate comprises at least 0.75% of the total precursor mixture.

22. The process according to claim 15, where the substrate comprises glass.

23. The process according to claim 22, done on the surface of a continuous glass ribbon during a float glass production process.

24. The process according to claim 23, where the precursor mixture is brought into contact with the surface of the glass at a point where the glass temperature is between 400° C. and 750° C.

25. The process according to claim 24, where the glass temperature is between 580° C. and 750° C.

26. The process according to claim 25, where the glass temperature is between 580° C. and 650° C.

27. The process according to claim 15, where the precursor mixture is maintained at a temperature of between 100° C. and 300° C., prior to contacting the glass surface.

28. The process according to claim 27, where the precursor mixture is maintained at a temperature of between 140° C. and 180° C., prior to contacting the glass surface.
